(19) United States
(12) Patent Application Publication
(10) Pub. No.: US 2023/0108864 A1
(43) Pub. Date: Apr. 6, 2023

(54) 3D Touch Control-Based Automobile Seat Adjustment Switch

(71) Applicant: Yanfeng Adient Seating Co., Ltd., Shanghai (CN)

(72) Inventors: Hao Huang, Shanghai (CN); Jun Mao, Shanghai (CN); Huijia Tao, Shanghai (CN); Chen Zhang, Shanghai (CN); Fangqin Li, Shanghai (CN); Shengfeng Gu, Shanghai (CN); Zhicheng Xu, Shanghai (CN)

(21) Appl. No.: 17/760,220

(22) PCT Filed: Jan. 14, 2021
(86) PCT No.: PCT/CN2021/071652

§ 371 Date: Aug. 5, 2022

(30) Foreign Application Priority Data
Feb. 14, 2020 (CN) 202020169371.3

(51) Int. Cl. H03K 17/96; B60N 2/02; H05K 1/18; H05K 1/02

(52) U.S. Cl. CPC H03K 17/9622; B60N 2/02; H05K 1/181; H05K 1/0277; H05K 2201/10151; H03K 2217/960755

(57) ABSTRACT

The present invention discloses a 3D touch control-based automobile seat adjustment switch, including an insulating cover plate, a touch sensor, a base, a feedback module, a circuit board, and a module assembly cover plate. A plurality of protruding or recessed touch control regions are arranged on the insulating cover plate. A plurality of independent touch sensors are attached to the plurality of touch control regions on the insulating cover plate, to form a 3D touch assembly, and the plurality of touch sensors are all connected to the circuit board. The circuit board is assembled on the module assembly cover plate, the module assembly cover plate and the feedback module are assembled on one surface of the base, the feedback module is connected to the circuit board, and an other surface of the base is assembled on the insulating cover plate. The present invention can control adjustment of an automobile seat by using a 3D touch assembly, thereby satisfying requirements for a reasonable vehicle space arrangement and lightweight accessories.

### TECHNICAL FIELD

The present invention relates to an automobile seat control switch, and in particular, to a 3D touch control-based automobile seat adjustment switch.

### BACKGROUND

With the development of automobile intellectualization, an automobile seat has increasingly more functions, and increasingly more corresponding function control switches are provided. At present, most of the control switches of the automobile seat are physical switches. The physical switch in the prior art has a relatively large size. An arrangement mode of the plurality of physical switches on the seat and circuit structures of the physical switches are complex, which require a larger arrangement space. Assembling is complicated and the mass is large, and an expanded hole may be caused after the physical switch is operated, which may lead to a risk of abnormal sticking. In addition, since the seat control switch is generally arranged on a side of a side shield, less space is reserved for operation by hand, which affects adjustment comfort.

In order to resolve the problem of sticking of the physical switch, touch control switch is mounted to seats of some vehicles. However, since the seat control switch is generally arranged on the side of the side shield, the side is a non-visual region and is required to be operated blindly. Most of the touch switches in the prior art have a planar structure and should be operated under a visible condition, which brings great inconvenience to the adjustment and control of the seat.

### SUMMARY

The present invention is intended to provide a 3D touch control-based automobile seat adjustment switch. In this way, adjustment of an automobile seat can be controlled by using a 3D touch assembly, thereby satisfying requirements for a reasonable vehicle space arrangement and lightweight accessories.

The present invention is implemented as follows:

A 3D touch control-based automobile seat adjustment switch is provided, including an insulating cover plate, a touch sensor, a base, a feedback module, a circuit board, and a module assembly cover plate. A plurality of protruding or recessed touch control regions are arranged on the insulating cover plate. A plurality of independent touch sensors are seamlessly attached to the plurality of touch control regions on the insulating cover plate, to form a 3D touch assembly, and the plurality of touch sensors are all connected to the circuit board. The circuit board is assembled on the module assembly cover plate, the module assembly cover plate and the feedback module are assembled on one surface of the base, the feedback module is connected to the circuit board, and an other surface of the base is assembled on the insulating cover plate. The automobile seat adjustment switch is assembled on a side shield of an automobile seat.

The feedback module is one or a combination of more than one of a vibration motor, a pressure element, an electromagnet, or a buzzer.

The feedback module is the vibration motor, and the vibration motor is arranged between the circuit board and the base.

The feedback module includes the vibration motor and the pressure element. The vibration motor is arranged between the circuit board and the base. The pressure element is a diaphragm pressure sensor and is attached between the circuit board and the module assembly cover plate.

The touch sensor includes a flexible substrate and a conductive wire, the conductive wire is printed on the flexible substrate, and the flexible substrate is seamlessly attached to surfaces of the touch control regions by using a double-sided tape.

The plurality of touch control regions are not in a same plane, and each touch control region forms an independent branch circuit with the circuit board through the touch sensor on the touch control region.

An area of the touch control region is not less than 5*5 mm.

An embedding opening is arranged on the side shield, so that the insulating cover plate is embedded in the embedding opening of the side shield in a matched manner, and the base is assembled on the side shield.

The insulating cover plate is directly mounted to the automobile seat as a non-hollowed-out side shield. The touch sensor, the base, the feedback module, the circuit board, and the module assembly cover plate are mounted to the non-hollowed-out side shield.

Compared with the prior art, the present invention has the following advantageous effects:

1. In the present invention, the 3D touch assembly is adopted, and a conventional physical switch is replaced by the touch switch, so that a volume is reduced by 30%, thereby realizing lightweight accessories such as the switch. In addition, molds such as a switch button is reduced, and manufacturing costs and the assembly difficulty are reduced, thereby avoiding a risk of switch sticking.

2. In the present invention, a protruding or recessed touch control region is adopted, which is convenient to identify a position of each function switch. Therefore, the requirement for blind operation is satisfied while increasing the space for operation by hand.

3. In the present invention, the independent touch sensors are adopted to respectively realize the adjustment functions of the automobile seat. A number, an arrangement position, and directions of the touch sensors may be adjusted or customized according to a model and a usage requirement, and the like. With a high modularity degree, the touch sensors may be arranged on surfaces of different shapes with high flexibility.

4. The present invention may be applicable to various switches of the automobile seat, a door and a window, an instrument panel, and the like, which has a wide range of applications and may be integrated with an accessory such as an ambient lamp to improve aesthetics and functionality of an automobile.

The present invention can control various adjustment modes of the automobile seat by using the 3D touch assembly, so that the vehicle space arrangement is more reasonable, blind operation of the seat touch switch can be realized, and the accessories such as the switch can meet the requirements for the light weight and low costs.

### BRIEF DESCRIPTION OF THE DRAWINGS

FIG. 1 is a schematic structural diagram of a 3D touch control-based automobile seat adjustment switch according to the present invention.

FIG. 2 is an exploded view of a 3D touch control-based automobile seat adjustment switch according to the present invention.

FIG. 3 is a bottom view of an insulating cover plate in a 3D touch control-based automobile seat adjustment switch according to the present invention.

FIG. 4 is an arrangement diagram of a touch control region in a 3D touch control-based automobile seat adjustment switch according to the present invention.

FIG. 5 is a front view of a seat back touch sensor in a 3D touch control-based automobile seat adjustment switch according to the present invention.

FIG. 6 is a bottom view of a seat back touch sensor in a 3D touch control-based automobile seat adjustment switch according to the present invention.

FIG. 7 is a front view of a lumbar support touch sensor in a 3D touch control-based automobile seat adjustment switch according to the present invention.

FIG. 8 is a bottom view of a lumbar support touch sensor in a 3D touch control-based automobile seat adjustment switch according to the present invention.

FIG. 9 is a schematic circuit diagram of a 3D touch control-based automobile seat adjustment switch according to the present invention.

FIG. 10 is a cross-sectional view of installation of one feedback module in a 3D touch control-based automobile seat adjustment switch according to the present invention.

FIG. 11 is a cross-sectional view of installation of an other feedback module of a 3D touch control-based automobile seat adjustment switch according to the present invention.

FIG. 12 is an operating principle diagram of a conductive touch structure of a 3D touch control-based automobile seat adjustment switch according to the present invention.

In the figure, 1. Insulating cover plate; 11. Touch control region; 2. Touch sensor; 21. Seat back touch sensor; 22. Lumbar support touch sensor; 3. Base; 4. Feedback module; 41. Vibration motor; 42. Pressure element; 5. Circuit board; 6. Module assembly cover plate; 7. Side shield; 71. embedding opening; 8. Main control module.

### DETAILED DESCRIPTION

The present invention will be further described below with reference to the accompanying drawings and specific embodiments.

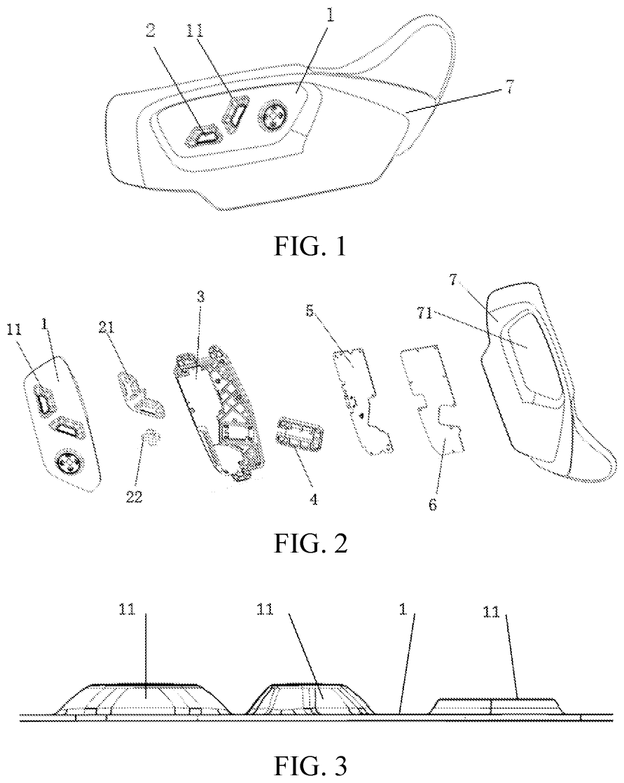

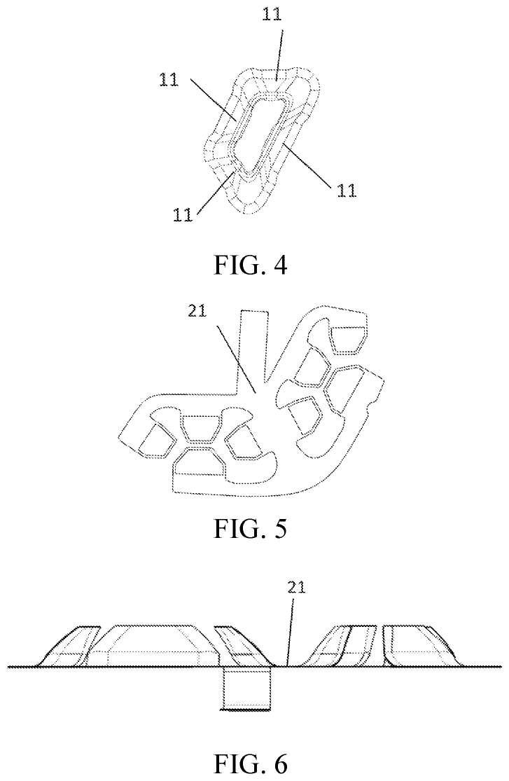

Referring to FIG. 1 and FIG. 2, a 3D touch control-based automobile seat adjustment switch is provided. The automobile seat adjustment switch includes an insulating cover plate 1, a touch sensor 2, a base 3, a feedback module 4, a circuit board 5, and a module assembly cover plate 6. Referring to FIG. 3 and FIG. 4, a plurality of protruding or recessed touch control regions 11 are arranged on the insulating cover plate 1. Different control functions may be distinguished by touching, so as to achieve blind operation. A plurality of independent touch sensors 2 are seamlessly attached to the plurality of touch control regions 11 on the insulating cover plate 1, to ensure sensitivity and reliability of the touch control and form a 3D touch assembly. In addition, the plurality of touch sensors 2 are all connected to the circuit board 5 by wires, so as to transmit a touch signal source. The circuit board 5 is assembled on the module assembly cover plate 6 by screws. The module assembly cover plate 6 and the feedback module 4 are assembled on one surface of the base 3 by screws, the feedback module 4 is connected to the circuit board 5 by a wire, and an other surface of the base 3 is assembled on the insulating cover plate 1 by screws. The base 3 of the automobile seat adjustment switch is assembled on a side shield 7 of an automobile seat by screws, which is quick and easy to assemble and disassemble and realizes aesthetics. The occupied space is greatly reduced, and an assembling requirement for a light weight is also achieved.

The feedback module 4 may be one or a combination of more than one of feedback elements such as a vibration motor, a pressure element, an electromagnet, or a buzzer. An appropriate feedback module 4 may be selected according to requirements for functionality and vehicle models.

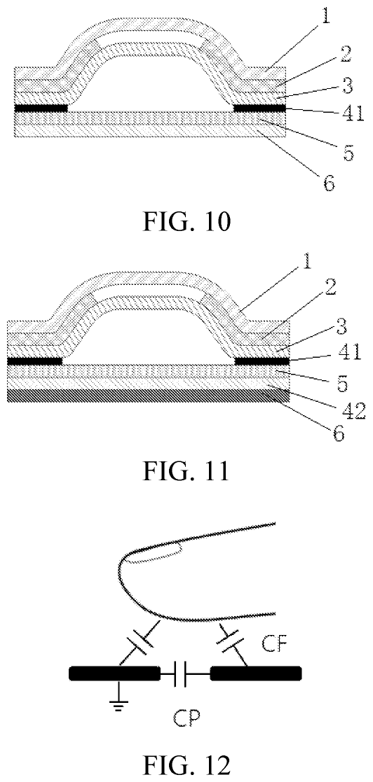

Referring to FIG. 10, when the feedback module 4 is a vibration motor 41, the vibration motor 41 is arranged between the circuit board 5 and the base 3. When the touch sensor 2 transmits the touch signal source to the circuit board 5, the circuit board 5 converts the touch signal source and outputs power to the vibration motor 41 to confirm contact between a finger and the touch sensor 2, thereby realizing touch feedback, which indicates that an adjustment function of the seat starts to be enabled, and the power is ON. Therefore, the circuit board 5 outputs a bus signal to a main control module 8 of the automobile seat to drive the main control module 8.

Referring to FIG. 11, when the feedback module 4 is the vibration motor 41 and a pressure element 42, the vibration motor 41 is arranged between the circuit board 5 and the base 3. The pressure element 42 may be a diaphragm pressure sensor and attached between the circuit board 5 and the module assembly cover plate 6. When the touch sensor 2 transmits the touch signal source to the circuit board 5, the circuit board 5 converts the touch signal source and outputs power to the vibration motor 41, to confirm the contact between the finger and the touch sensor 2, thereby realizing first-level touch feedback. The finger continues to press the touch sensor 2, the pressure element 42 deforms and sends a signal to the circuit board 5, and the circuit board 5 drives the vibration motor 41 to realize second-level touch feedback, which indicates that an adjustment function of the seat starts to be enabled, and the power is ON. Therefore, the circuit board 5 outputs the bus signal to the main control module 8 of the automobile seat to drive the main control module 8. The diaphragm pressure sensor, a capacitive pressure sensor, an infrared pressure sensor, and the like may be configured as the pressure element 42 to detect slight deformation of the insulating cover plate 1.

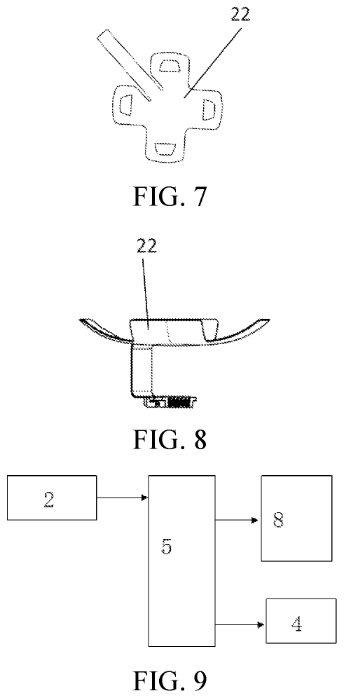

Referring to FIG. 5 to FIG. 8, the touch sensor 2 includes a flexible substrate and a conductive wire. The conductive wire is printed on the flexible substrate by a screen printing process, and the flexible substrate is seamlessly attached to a surface of the touch control region 11 by using a double-sided tape, so that a conductive touch structure is formed between the touch sensor 2 and the finger. Generally, the touch sensor 2 may be manufactured into a seat back touch sensor 21 and a lumbar support touch sensor 22, to respectively satisfy requirements for seat back control and lumbar support control of the automobile seat.

Preferably, the flexible substrate may be made of polyethylene terephthalate (PET) or polycarbonate (PC). The conductive wire may be made of a copper foil, PEDOT (PEDOT is a polymer of 3,4-ethylenedioxythiophene monomers), a metal grid, a nano silver wire, and the like. The conductive wire is printed on the flexible substrate by the screen printing process to form a touch layer with certain flexibility. The flexible substrate may be seamlessly pasted on the touch control region 11 by using an adhesive such as a non-substrate double-sided tape, to ensure reliability of touch sensing of each touch sensor 2.

Preferably, depending on different types of touch sensors 2, touch sensing methods of the touch sensors 2 may be sliding, pressing, and the like. Touch signal sources of the touch sensor 2 may include a touch time, a number of touches, coordinates of a touch point, a movement speed of the touch point, a movement distance of the touch point, and the like.

The plurality of touch control regions 11 are not in a same plane, and each touch control region 11 forms an independent branch circuit with the circuit board 5 through the touch sensor 2 on the touch control region 11. Each touch control region 11 may be identified by the recessed or protruding structure and the distribution position, which is convenient for the blind operation to control different adjustment modes of the automobile seat. The plurality of touch control regions 11 may include a slideway backward region, a slideway forward region, a front down region, a front up region, a back down region, a back up region, a backrest backward region, a backrest forward region, a lumbar support forward region, a lumbar support backward region, a lumbar support upward region, and a lumbar support downward region, so as to respectively meet various adjustment requirements for the seat back and the lumbar support of the current vehicle seat.

An area of the touch control region 11 is not less than 5*5 mm, and a size of the touch control region 11 may be adjusted according to an actual requirement, so as to satisfy effectiveness of contact between the finger and the touch control region 11.

An embedding opening 71 is arranged on the side shield 7, so that the insulating cover plate 1 can be embedded in the embedding opening 71 of the side shield 7 in a matched manner, and the insulating cover plate 1 and the side shield 7 may be combined into a plastic member. The base 3 may be assembled on the side shield 7 by screws, so that the appearance is beautiful, assembling is convenient, and the space required for assembling is reduced.

Preferably, the insulating cover plate 1 may be made of a non-conductive material, such as glass, plastic, and bakelite.

Preferably, the insulating cover plate 1 may also be used instead of the side shield. When the insulating cover plate 1 is directly mounted to the automobile seat as a non-hollowed-out side shield, the touch sensor 2, the base 3, the feedback module 4, the circuit board 5, and the module assembly cover plate 6 are mounted to the non-hollowed-out side shield, that is, a back side of the insulating cover plate 1, so as to further realize the light weight and a simplified design of the automobile seat.

Referring to FIG. 9, the operating principle of the present invention is as follows. A user touches the touch control region 11 by a finger. The touch sensor 2 on the touch control region 11 and the finger form a parallel plate capacitor. The touch sensor 2 transmits the touch signal source to the circuit board 5, and the circuit board 5 converts the touch signal source, and outputs the power to the feedback module 4. The feedback module 4 and the circuit board 5 realize touch feedback, which indicates that the finger identifies the touch control region 11 and causes the circuit board 5 to operate. The circuit board 5 outputs the bus signal to the main control module 8 of the automobile seat, so that the main control module 8 realizes the seat adjustment function corresponding to the touch control region 11. When the finger remains in contact with the touch sensor 2, the seat always performs a corresponding adjustment operation. When the finger is separated from the touch sensor 2, the seat immediately stops the corresponding adjustment operation.

Referring to FIG. 12, a parasitic capacitance CP represents a capacitance between a pin of the touch sensor 2 and the ground, and a finger capacitance CF represents a capacitance between a human body and the ground. Both the capacitances have a same nature.

When the finger does not contact the touch sensor 2, a total sensor capacitance CX is equal to the parasitic capacitance CP. When the finger contacts the touch sensor 2, the total sensor capacitance CX is equal to the parasitic capacitance CP plus the finger capacitance CF.

A capacitance value of the finger capacitance CF may be calculated by Equation (1):

CF=ε0*εr*A/d (1)

ε0 is a dielectric constant of air, εr is an insulation constant (that is, a relative dielectric constant) of the insulating cover plate 1, A is a contact area between the finger and the insulating cover plate 1 (that is, an area of the touch control region 11), and d is a thickness of the side shield 7.

A shape, a size, and a protruding or recessed structure of the touch control region 11 may be adjusted or customized according to different vehicle models, usage requirements, and the like, with high flexibility and strong manufacturing feasibility.

The foregoing descriptions are merely preferred embodiments of the present invention, but are not intended to limit the protection scope of the present invention. Any modification, equivalent replacement, or improvement made within the spirit and principle of the present invention shall fall within the protection scope of the present invention.

What is claimed is:

1. A 3D touch control-based automobile seat adjustment switch, comprising an insulating cover plate, a touch sensor, a base, a feedback module, a circuit board, and a module assembly cover plate, wherein a plurality of protruding or recessed touch control regions are arranged on the insulating cover plate, a plurality of independent touch sensors are attached to the plurality of touch control regions on the insulating cover plate, to form a 3D touch assembly, and the plurality of touch sensors are all connected to the circuit board; the circuit board is assembled on the module assembly cover plate, the module assembly cover plate and the feedback module are assembled on one surface of the base, the feedback module is connected to the circuit board, and an other surface of the base is assembled on the insulating cover plate.

2. The 3D touch control-based automobile seat adjustment switch according to claim 1, wherein the feedback module is one or a combination of more than one of a vibration motor, a pressure element, an electromagnet, or a buzzer.

3. The 3D touch control-based automobile seat adjustment switch according to claim 2, wherein the feedback module is the vibration motor, and the vibration motor is arranged between the circuit board and the base.

4. The 3D touch control-based automobile seat adjustment switch according to claim 2, wherein the feedback module comprises the vibration motor and the pressure element, the vibration motor is arranged between the circuit board and the base, and the pressure element is a diaphragm pressure sensor and is attached between the circuit board and the module assembly cover plate.

5. The 3D touch control-based automobile seat adjustment switch according to claim 1, wherein the touch sensor comprises a flexible substrate and a conductive wire, the conductive wire is printed on the flexible substrate, and the flexible substrate is seamlessly attached to surfaces of the touch control regions by using a double-sided tape.

6. The 3D touch control-based automobile seat adjustment switch according to claim 1, wherein the plurality of touch control regions are not in a same plane, and each touch control region forms an independent branch circuit with the circuit board through the touch sensor on the touch control region.

7. The 3D touch control-based automobile seat adjustment switch according to claim 1, wherein an area of the touch control region is not less than 5*5 mm.

8. The 3D touch control-based automobile seat adjustment switch according to claim 1, wherein an embedding opening is arranged on a side shield of an automobile seat, so that the insulating cover plate is embedded in the embedding opening of the side shield in a matched manner, and the base is assembled on the side shield.

9. The 3D touch control-based automobile seat adjustment switch according to claim 1, wherein the insulating cover plate is configured as a side shield of an automobile seat.
